(19) United States
(12) Patent Application Publication
(10) Pub. No.: US 2010/0185925 A1
(43) Pub. Date: Jul. 22, 2010

(54) Differential Locally Updating Viterbi Decoder

(76) Inventors: Janne Maunu, Turku (FI); Ari Paasio, Littoinen (FI); Mika Laiho, Helsinki (FI)

Correspondence Address: STIENNON & STIENNON, 612 W. MAIN ST., SUITE 201, P.O. BOX 1667, MADISON, WI, 53701-1667, US

(21) Appl. No.: 12/602,068

(22) PCT Filed: May 7, 2008
(86) PCT No.: PCT/FI2008/000056

§ 371 Date: Nov. 27, 2009

(30) Foreign Application Priority Data
May 29, 2007 (FI) 20070423

(51) Int. Cl. H03M 13/41; G06F 11/10

(52) U.S. Cl. 714/792; 714/E11.032; 714/795

(57) ABSTRACT

The present invention relates to differential, locally updating Viterbi decoder characterized in that it contains connection management block (802, 810, 812) which enables decoding a bit per cycle by trellis diagram uniting (810) and distributing procedure (812). Furthermore, the invention is also characterized in that it contains a path metric update block, in which the monotonical growth of state metrics is avoided by a bounding procedure in a path metric update (808).

### TECHNICAL FIELD OF THE INVENTION

The present invention relates to a Viterbi decoder with differential processing, consisting of separate data processing for output decoding and for local cyclic state metric update, i.e. a differential locally updating Viterbi decoder.

### BACKGROUND OF THE INVENTION

Viterbi decoders are employed in several modern telecommunication systems as a part of their forward error control mechanisms. Viterbi decoders are used in wireless local area, networks, digital cellular phones, satellite communication, digital video broadcasting and digital wireless receivers. They are also employed in ultra-wideband (UWB) systems ideally suited for short-range and high-speed data transmission.

A Viterbi decoder usually consists of many arithmetic computation blocks, which are connected together in an upper hierarchy level. In each block the typical functional units are branch metric calculation unit, add-compare-select unit and path memory unit. The branch metric calculation unit calculates the likelihoods of all the possible codewords for the received channel output sequence. The add-compare-select unit updates the probabilities of the state transitions according to the new branch metrics, compares the two competitive probabilities (i.e. paths) of each block and selects the most probable path. The probabilities of different states and transitions between the states are memorized into the path memory.

In a Viterbi decoder network the transitions between the states as a function of time are described with the aid of a trellis diagram. The states in a trellis diagram represent the memory content of the encoder. The encoder is a finite state machine and its code rate is defined as the number of input bits to output bits. The constraint length of the encoder is a measure of the memory within a code. The encoded codewords are produced by modulo-two adders. In the encoding phase it is usually assumed that the encoder is initially loaded into the zero-state. Depending on the first input bit, there are two possible states in the encoder after one clock cycle. Each of these states has again two possible state transitions. The trellis diagram is expanded until it reaches its overall size (the maximum number of states), determined by the number of memory elements in the encoder. After a fixed number of bits the most probable path through the trellis diagram is determined by the Viterbi algorithm.

The Viterbi algorithm determines the maximum likelihood path through the trellis diagram for a received noisy bit stream. The maximum likelihood path is characterized with the aid of a branch metric and a path metric. The branch metrics represent the probabilities of receiving the signal for the encoder output sequence. The branch metrics accumulated through the state transitions construct a path metric. The path metrics from the initial state to the current state are stored as state metrics of the decoder. After the trellis diagram is expanded into the maximum number of states, there are two competing paths entering each state, from which the decoder discards the path more distant from the observation. The retained path is stored into the path memory as a survivor metric. After a fixed number of input bits the maximum likelihood path is traced back from the final stage to the initial stage with the aid of the contents of the path memory. Because of the trace-back procedure the selection of a suitable path memory structure requires a trade-off between speed and performance.

Elimination of a speed-performance trade-off in path memory design requires decoding on other basis than the survivor memory. The path memory unit is also the only digital computation block in the decoder utilizing analogue processing techniques, whereas an analogue to digital converter is used together with digital Viterbi decoders.

In modern high-speed applications, an analogue Viterbi decoder eliminates the need for a high-speed and power consuming analogue-to-digital converter due to the analogue characteristics of the received noisy sequence. Since the path memory unit is the only digital building block in many Viterbi decoder realizations utilizing analogue processing techniques, a pure analogue Viterbi decoder can be constructed if the requirement for the digital path memory unit can be avoided.

Some analogue implementations for avoiding the speed bottlenecks of the digital Viterbi decoder together with the exclusion of the analogue-to-digital converter from the decoder front end have been described. In M. H. Shakiba, D. A. Johns, K. W. Martin ‘An integrated 200-MHz 3.3-V BiCMOS class-IV partial response analog Viterbi decoder’, IEEE journal of solid-state circuits, vol. 33, January 1998 an analogue Viterbi decoder with a digital register-exchange path memory was proposed. It was shown that this prior art can be realized by utilizing a few simple analogue building blocks. The robustness of this prior art to the various fabrication imperfections was also verified by simulations.

In an article by K. He, G. Cauwenberghs, ‘Integrated 64-state parallel analog Viterbi decoder’, proceedings of the IEEE international symposium on circuits and systems, May 2000 a mixed-signal architecture for state-parallel Viterbi decoder, including analogue Add-Compare-Select module and digital path memory, was proposed. The second prior art used a (177,133) convolutional code with a code rate of one half and constraint length of seven. Parallel state metric calculation enables the convolutional codes with constraint lengths up to seven to be used, which increases the coding gain of the Viterbi decoder as compared to convolutional codes with smaller constraint lengths. In the second prior art, branch metric calculation, path metric accumulation, comparison and selection are included in the Add-Compare-Select module. The second prior art does not eliminate all the challenges of the Viterbi decoder design for high-speed applications: it utilizes trace-back digital path memory for storing the survivor path information. Furthermore, the path memory is also applied for generating the decoded output by tracing back the optimal path through the trellis diagram according to the contents of the path memory.

In an article by A. Demosthenous, J. Taylor, ‘A 100-Mb/s 2.8-V current-mode analog Viterbi decoder’, IEEE journal of solid-state circuits, vol. 37, no. 7, July 2002 the first current-mode analogue Viterbi decoder is described. The third prior art realized an analogue Viterbi decoder with a few simple building blocks. In the third prior art, a technique for relaxing the main source of cumulative analogue errors is proposed. This prior art is not well suited for convolutional codes with large constraint lengths because it utilizes a register-exchange digital path memory, which is known to be complicated to design for larger codes. The third prior art proposed a 4-state hybrid Viterbi decoder with a constraint length of three and the area of the digital memory is about two thirds of the analogue Viterbi decoder core.

In a mixed-mode Viterbi decoder consisting of an analogue processing core and a digital path memory the high-speed operation requires a register-exchange type path memory structure. For larger convolutional codes a reasonable coding gain is conventionally achieved by a trace-back type of path memory, which is less complicated to design and requires considerably less area. This trade-off between speed and performance can be avoided if a pure analogue Viterbi decoder is designed, where the need for the digital memory is eliminated. In U.S. Pat. No. 6,968,495, ‘Super high-speed Viterbi decoder using circularly connected 2-dimensional analog processing cell array’, the path memory is excluded and the decoding is accomplished by circulating data around the networks. This fourth prior art employs a two-phase Viterbi decoding scheme. First the accumulated error metrics are calculated by forward processing. Second, decoding is performed by applying a negative triggering wave, which propagates through the network, and monitoring the voltage level simultaneously at the output. This approach complicates the hardware realization of the Viterbi decoder, since the triggering wave takes time K stages to propagate, if the constraint length of the convolutional code is denoted by K.

In an article by A. Demosthenous, C. Verdier, J. Taylor, ‘A new architecture for low power analogue convolutional decoders’, proceedings of the IEEE international symposium on circuits and systems, vol. 1, 1997 a modified feedback decoding algorithm is presented, where the path memory of the Viterbi decoder is excluded by distributing the trellis network into two sub-trellises to model two competing paths (two competing codewords). In this fifth prior art the decision on the maximum likelihood path is made by comparing the minimum values of the two sub-trellises after their expansion into the maximum number of states. The fifth prior art utilizes a symbol storage block to recover the state metrics for consecutive decoding stages and the state metrics. In the fifth prior art the path metrics are reseted to zero after each decoding cycle and the employed decoding depth is several times the constraint length of the convolutional code. Therefore, this approach is not suitable for convolutional codes with large constraint lengths at high data rates. This limits the number of applications, since better error correcting capability can be achieved by applying convolutional codes with larger constraint lengths. Moreover, this prior art is not suitable in modern wireless communication systems, where data rates up to hundreds of megabits are required.

### SUMMARY OF THE PRESENT INVENTION

It is an objective of the present invention to overcome or at least mitigate the disadvantages of the prior art. The present invention provides a differential, locally cyclic updating Viterbi decoder that enables the trace-back memory to be excluded, while maintaining the high-speed operation. The purpose of the invention presented here is to enable convolutional codes with larger constraint lengths than in the fifth prior art to be used.

Another purpose of the invention presented here is to achieve higher decoding speed than in the fifth prior art with the aid of local cyclic state metric update. The updating procedure enables a decoding depth of one to be used after the initial loading period, i.e. after the state metrics for all the states have been calculated. The decoder structure presented here is based on consecutive trellis diagram distributing and uniting procedure, which is used for determining the decoded output and for local state metric update between the decoding cycles. According to the present invention the same hardware can be recursively used for the trellis diagram uniting and distributing procedure at consecutive decoding cycles.

Since the state metrics tend to grow monotonically with time the state metrics are reseted to zero between the decoding cycles in the fifth prior art. To overcome this limitation, a path metric renormalization technique based on averaging the path metrics was proposed in the third prior art. To keep the metrics in an appropriate range for the local state metric update, the invention presented here also utilizes a bounding procedure. This procedure can be made also on other basis than the renormalization tehnique presented in the third prior art, e.g. global minimum subtraction and state metric downscaling.

Referring to J. Maunu, M. Laiho, A. Paasio, ‘A differential approach to analog Viterbi decoding’, proceedings of the 49^{th} IEEE Midwest symposium on circuits and systems, the decoding speed of the trellis diagram distribution based decoding proposed in the fifth prior art can be increased by using decoding depth that is equal to one after a trellis diagram expansion into its whole size. In the present invention a local cyclic updating procedure is introduced for this purpose.

In the present invention, the example convolutional codes with a code rate of one half are considered, but the method presented here is applicable also for the codes with other code rates. The state relations of an example convolutional code are illustrated in FIG. 1 in the form of a trellis diagram. Constant K is the constraint length of the convolutional code and the state relations are valid for every value of j, 0·j·2^{K-1}−1. The number of states N in a trellis diagram is dependent on the constraint length K, N=2^{K-1}.

The maximum likelihood path through the trellis diagram is the one that has the largest log-likelihood function:

$$ln [ {P}_{Y} ( Y \vert {C}_{m} ) ] = {\sum }_{{n}^{′} = 1}^{∞} ln [ {P}_{Y} ( {Y}_{{n}^{′}} \vert {C}_{{mn}^{′}} ) ] ,$$

where Cₘ is the encoder output sequence corresponding to path m and Y is the received analogue signal. The components on the summation are accumulated on the individual paths as branch metrics. For a Gaussian channel the maximum likelihood path is the one with minimum Euclidean distance. In high-speed applications, convolutional codes with one bit redundancy (R=½) are most widely used. The branch metric (BM) calculation for a convolutional code with R=½ can be presented as: BM=(Y₁−C₁)²+(Y₂−C₂)², where Y₁ and Y₂ are the received output signals and C₁ and C₂ are the particular codewords associated within a branch.

The branch metrics accumulated along a path construct a path metric. The maximum likelihood path from the initial state to the current state is stored as a state metric. After the trellis diagram has expanded into its overall size, there are two competing paths entering each state. From them, the decoder selects the one, which is closest to the received signal and discards the other. The path metric (PM) update or add-compare-select operation for each state can be described as:

$${PM}_{j} = {min}_{i} ⌊ {PM}_{i} + {BM}_{i , j} ⌋ ,$$

where j denotes the current state and i denotes the set of states, from which the paths are connected to the current state according to the trellis diagram.

In FIG. 2 the differential locally updating Viterbi decoder for an example (2,1,3) convolutional code is presented. The structure presented here is applicable both for analogue and digital decoder realizations. In this decoder the upper trellis network corresponds to the input bit ‘0’ and the lower network corresponds to the input bit ‘1’, similarly to the fifth prior art. Both of these trellis networks are expanded until they reach their overall size N, which is 4 in this example case. After that, the first decoder output on the receiver side is produced depending on which network contains the maximum likelihood path. In the fifth prior art, the state metrics are reseted to zero between the decoding cycles, since the state metrics otherwise increase monotonically with time. This is due to the fact that the new branch metrics are always added to the previous state metrics according to the Viterbi algorithm. In the third prior art an averaging based renormalization method is applied for the path metrics to avoid the accumulation of the metrics as a function of time. In the present invention a bounding procedure is applied for the state metrics between the decoding cycles. In an example bounding procedure the value of the maximum likelihood path in the previous decoding cycle is subtracted from all the path metrics at the current decoding cycle and the path metrics are further downscaled by a proper downscaling factor. Therefore, the present invention is able to keep the state metrics within a predetermined range. After the initialization period, the decoded output can be produced at every decoding cycle. If the constraint length of the convolutional code is denoted by K, the decision on the polarity of the received bit is accomplished after receiving K succeeding bits by comparing the outputs of the two K-state minimum circuits.

In FIG. 1 the competing paths entering each state come into it from even and odd states respectively after the trellis expansion into its capacity, i.e. after the initialization period. The present invention uses this property in the local state metric update as shown in FIG. 2. In this example case, the upper of the sub-trellis networks uses minimum blocks for even states and the lower network uses minimum blocks for odd states. In other words, the two-input minimum circuits are distributed between the sub-trellis networks. The output of the two-input minimum circuits are connected to the corresponding states thus defining the current survivor metric for each state. At the next decoding cycle, these survivor metrics are summed with the new branch metrics, the global minimum metric from the previous decoding cycle is subtracted from the resulting path metrics, the metrics are downscaled by a proper factor and the results are fed to the two-input minimum circuits according to the trellis diagram connections. The codewords closest to observation are determined for both of the sub-trellis networks by taking the minimum values from the state metrics. By comparing these minimum values, the maximum likelihood path is produced into the decoder output.

The present invention utilizes distributed trellis diagram to produce the decoded output and reunited trellis diagram for the local state metric update. After the initialization phase, the decoded output is produced on every decoding cycle, since the value of the previous maximum likelihood path is subtracted from the path metrics and the metrics are further downscaled. The differential decoding procedure with a local state metric update is shown in FIG. 2 and it can be viewed as a four-phase operation as shown in FIGS. 3-6. The initialization period of the present invention is shown in FIG. 3. At this period the trellis diagram is distributed into two sub-trellises in such a way that the upper trellis network corresponds the input bit ‘0’, whereas the lower network corresponds the input bit ‘1’. During the initialization period the two sub-trellises are expanded and achieve their overall size after the first K bits have been received, constant K denoting the constraint length of the convolutional code. The second, third and fourth phase of the functional procedure are defined as a decoding cycle or cycle, since these phases are recursively repeated, which results in a decoding depth of one after the initialization period.

### BRIEF DESCRIPTION OF THE DRAWINGS

For a better understanding of the present invention and in order to show how the same may be carried into effect reference will now be made, by way of example, to the accompanying drawings, in which:

FIG. 1 shows a trellis diagram state relations. The two competing paths entering each state come into it from even and odd previous states. This property is used in the local state metric update of the differential Viterbi decoder.

FIG. 2 illustrates the trellis diagram structure of the present invention for an example (2,1,3) convolutional code. The two sub-trellis networks, the decoded output generation blocks and the state connections during the local state matric update are shown. The functional procedure of the present invention is illustrated in more detail in FIGS. 3-6.

FIG. 3 shows the initialization period of the operation for the present invention during which the first decoded output is produced.

FIG. 4 shows the second phase of the operation for the present invention during which the two sub-trellis networks are locally reunited and the survivor metrics for each state are determined.

FIG. 5 shows the third phase of the operation for the present invention during which the survivor metrics are fed back to the preceding decoding stage and the trellis diagram is redistributed into the two sub-trellises.

FIG. 6 shows the fourth phase of the operation for the present invention during which the decoded output is determined again by comparing the metrics of the two sub-trellis networks.

FIG. 7 shows the structure of an example (2,1,7) convolutional encoder.

FIG. 8 shows a conceptual block diagram of the differential, locally updating Viterbi decoder for an example (2,1,7) convolutional code.

FIG. 9 shows a flowchart illustrating the method of the present invention.

### DETAILED DESCRIPTION OF CERTAIN EMBODIMENTS

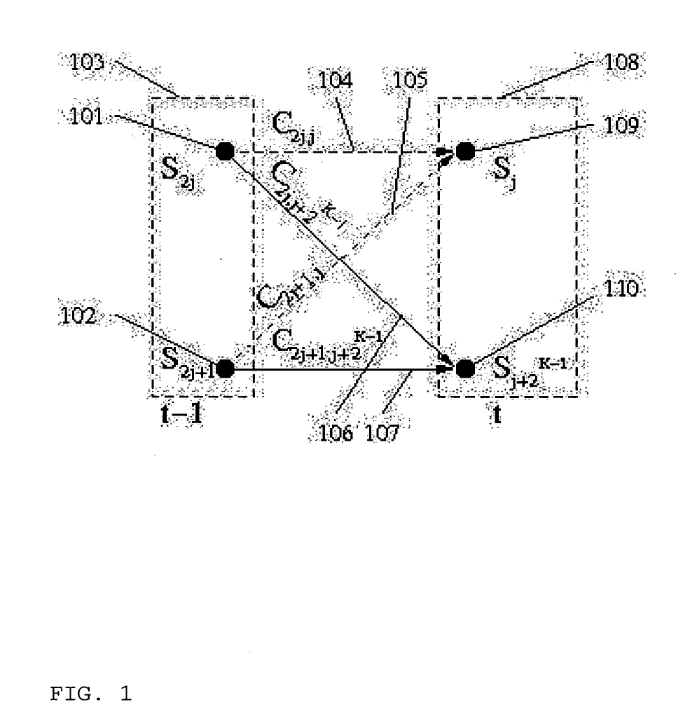

FIG. 1 shows the state relations of an example convolutional code with the code rate R=½ in the form of a trellis diagram. The constraint length of the convolutional decoder is denoted by K and the state relations are valid for every value of variable j, 0·j·2^{K-1}−1. The number of states (N) in a trellis diagram is dependent on the constraint length K (N=2^{K-1}). After the trellis diagram has expanded into its capacity, the competing paths entering each state come into it from even and odd previous states 101,102. During the first K-1 incoming bits the first input bit is shifted by K-1 bit positions in the convolutional encoder. Therefore, the even states correspond to the first input bit ‘0’, whereas the odd states correspond to the input bit ‘1’ after K-1 cycles 103. In FIG. 1, the labels of the branches indicate the corresponding code words between the state transitions 104, 105, 106, 107. After the first K bits have been received 108, there are two competing paths entering each state 109, 110. By distributing the previous states 101, 102 between the two sub-trellises, the first decoded output can be determined after first K bits have been received 108.

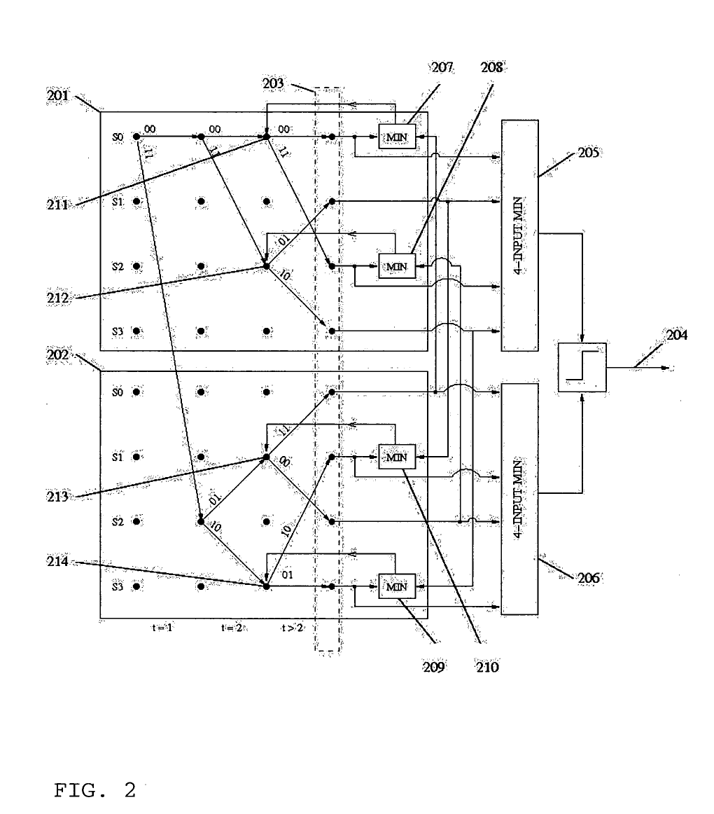

The differential Viterbi decoder described in the present invention consists of two sub-trellises. FIG. 2 shows the differential decoder for an example (2,1,3) convolutional code. The upper trellis network 201 corresponds to the input bit ‘0’ and the lower network 202 corresponds to the input bit ‘1’. Both of these networks are expanded until they reach their overall size (N=4) 203. After that the first decoder output is produced depending on which network contains the maximum likelihood path 204. Since the state metrics are kept within a predetermined range by a bounding procedure, the decoded output can be produced at every cycle after the initialization period thus enabling on-line decoding. Therefore, the decision on the polarity of the received bit is accomplished after K succeeding bits have been received by comparing the output of the K-state minimum circuits 205, 206. From FIG. 1 it can be observed that the two competing paths entering each state come from even and odd previous states. Therefore, in FIG. 2 the upper of the sub trellises contains two-input loser-take-all blocks for the even states 207, 208 and the lower sub-trellis have similar blocks for the odd states 209, 210. The outputs of the two-input loser-take-all circuits are connected to the corresponding states thus defining the current survivor metric for each state 211, 212, 213, 214. At the decoding cycle these survivor metrics are summed with the new branch metrics and the results are fed to the two-input minimum circuits according to the trellis diagram connections. The codewords closest to received signal are determined and the decoded output is produced by comparing the minimum values of the two sub-trellises.

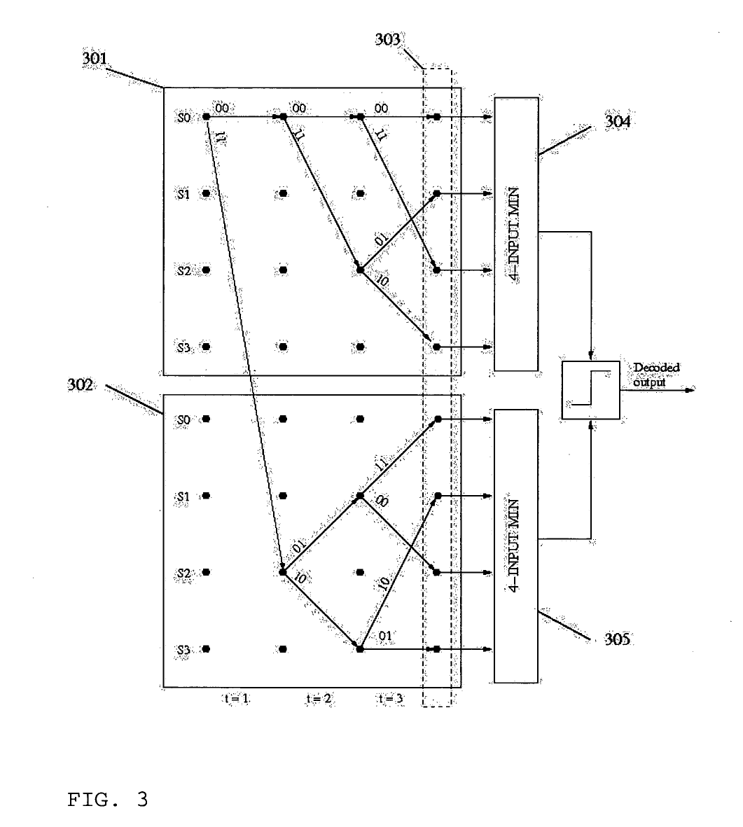

The differential Viterbi decoder utilizes a distributed trellis diagram to produce the decoded output and reunited trellis diagram for the local state metric update. In an example embodiment, the functional procedure of the present invention has four different phases described in FIGS. 3-6. FIG. 3 shows the initialization period, where the trellis diagram is divided into the two sub-trellises 301, 302. These two sub-trellis networks are expanded until they reach their capacity 303. When the transition probabilities are calculated for all the states 303, the maximum likelihood paths are determined for both of the sub-trellises by four-input minimum circuits 304, 305. The decoded output is produced by comparing those minimum values of the two sub-trellises.

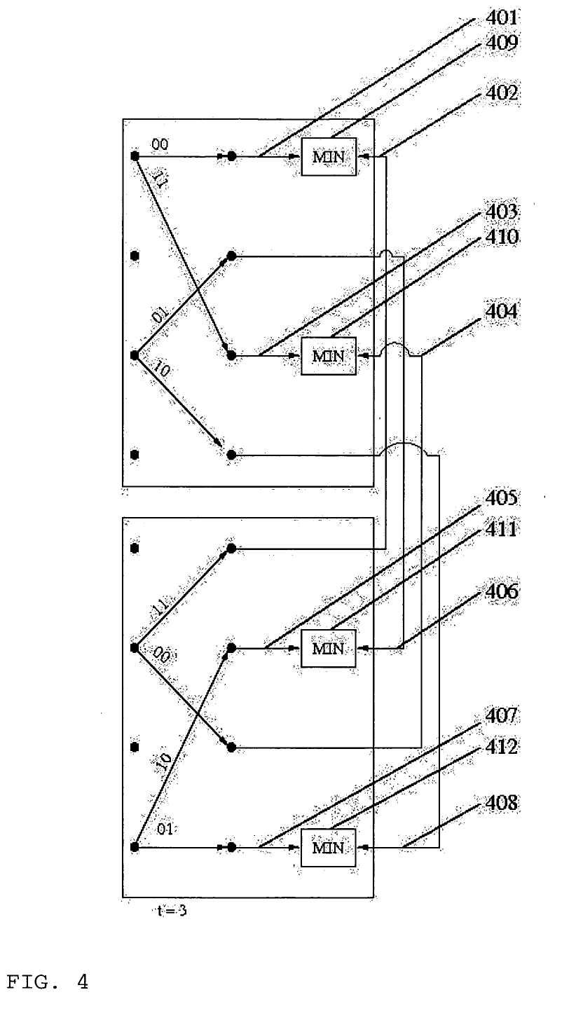

FIG. 4 shows the second phase of the operation for the present invention. At this phase the state metrics are locally updated by reuniting the two sub-trellises into a single trellis diagram during this operation. In other words, there are two competing paths entering each state 401, 402, 403, 404, 405, 406, 407, and 408. From the competing paths the survivor (maximum likelihood) path can be determined, e.g. by the two input minimum circuits 409, 410, 411 and 412.

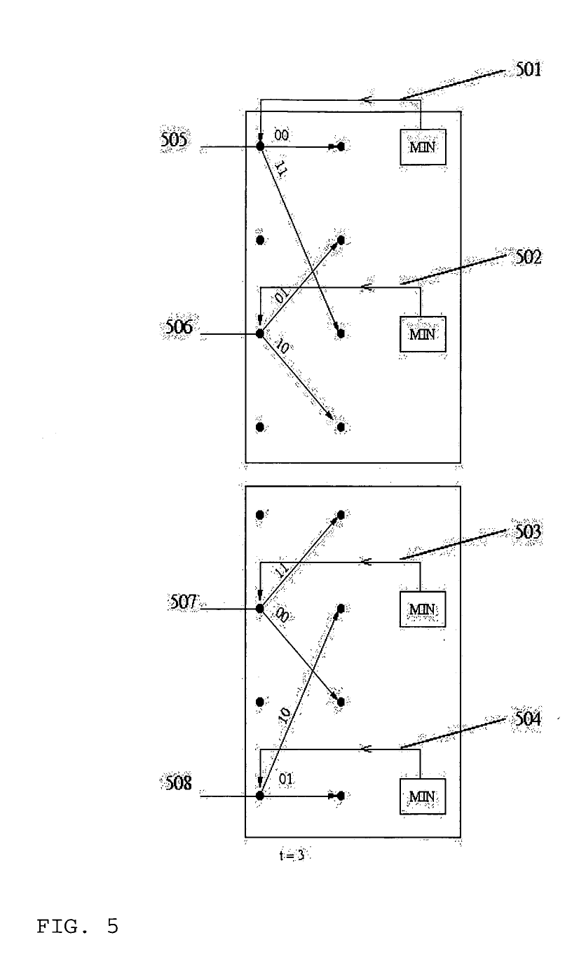

The third phase of the operation of the present invention is shown in FIG. 5. In this phase, the survivor metrics are fed back to the previous decoding stage 501, 502, 503 and 504. Furthermore, the locally updated sub-trellises are distributed again into the two sub-trellises in such a way that the upper network consists of the even states 505 and 506, whereas the odd states 507 and 508 are processed by the lower network.

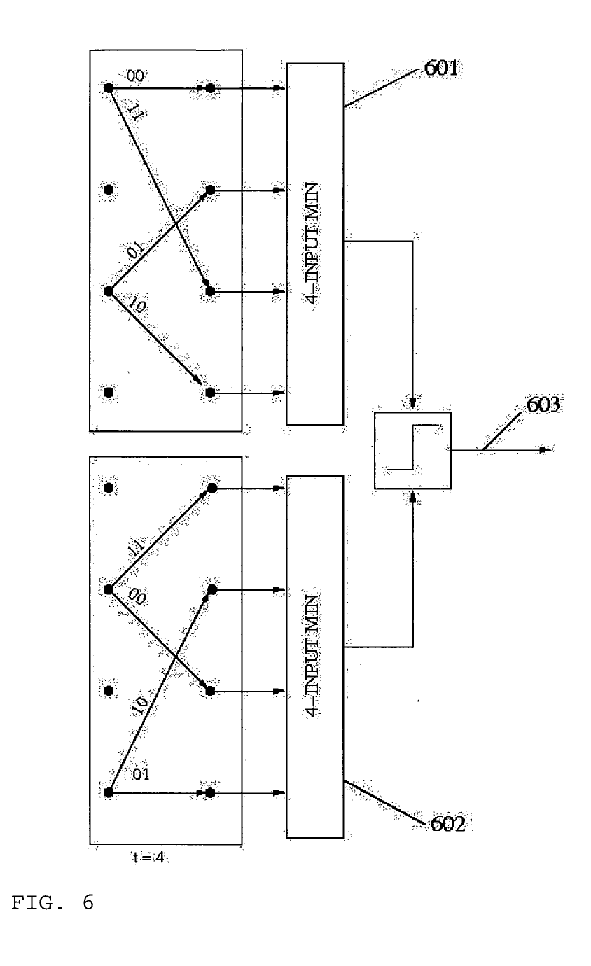

The fourth operation phase of the inventive concept of the present invention is shown in FIG. 6. At this phase the decoded output is again determined by comparing the minimum values of the two sub-trellis networks 601 and 602. Among the functional operations of the present invention, which were shown in FIGS. 3-6, the second, third and fourth phases are recursively repeated. Thus, the decoded output can be produced on-line and the state metrics are locally updated according to the trellis reuniting-redistributing procedure.

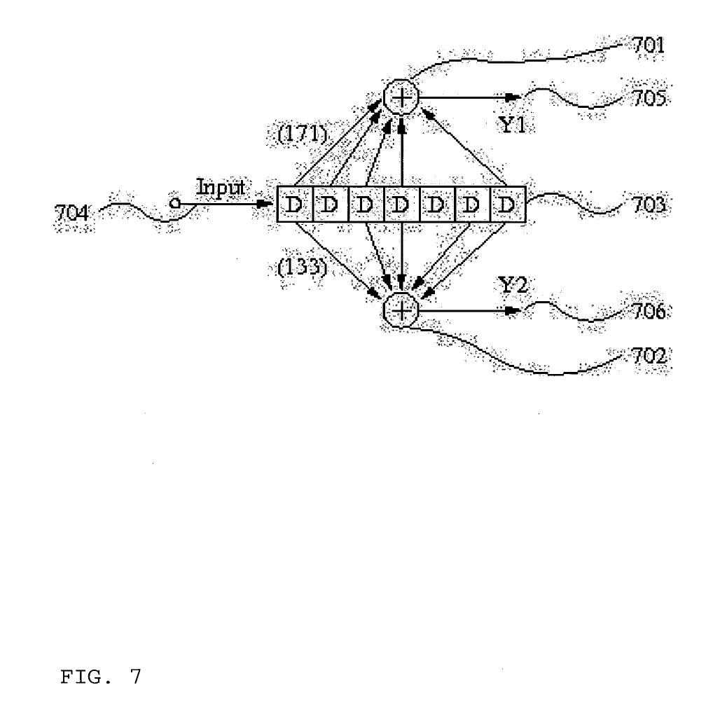

FIG. 7 shows an example (2,1,7) convolutional encoder. The encoder consists of two modulo-2 adders 701, 702 and a seven-bit shift register structure 703. The number of states N is dependent on the constraint length K of the convolutional code, N=2^{K-1}. The first bit of the shift register 703 is defined as an input bit and the last six bits are defined as a state vector, which results in a 64-state finite-state machine. Hence, the trellis diagram corresponding the (2,1,7) convolutional code consists of 64 states. From a single input bit 704 the encoder generates two output bits by applying industry standard generator polynomials g₀=171₈ and g₁=133₈ 705,706.

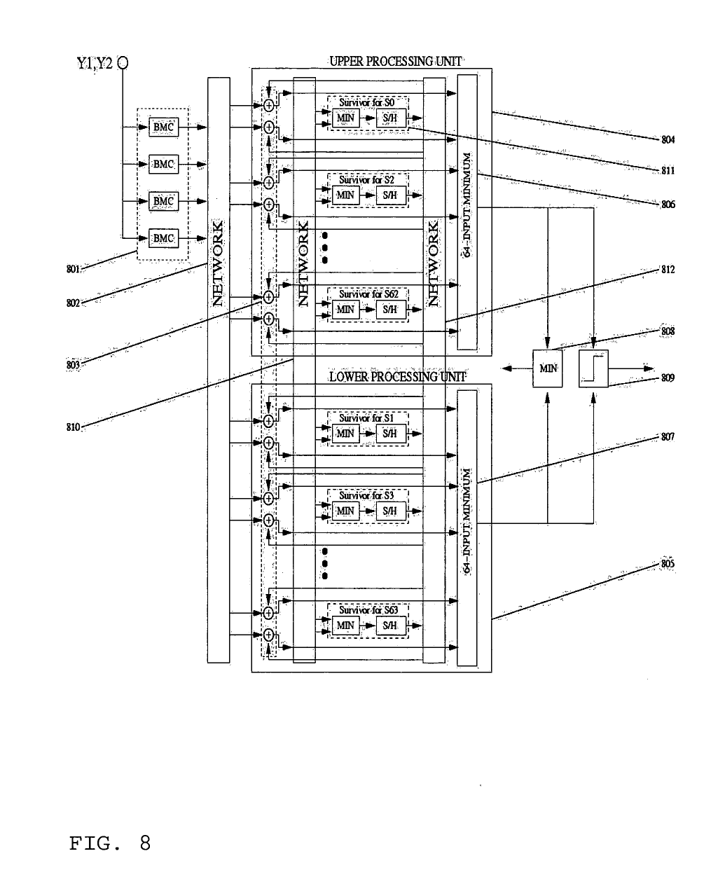

FIG. 8 shows a block diagram of the differential, locally updating Viterbi decoder for a (2,1,7) convolutional code. In a hardware realization of the decoder, all these blocks are not physically required, but they are used here to illustrate the operation of the present invention. For a particular incoming analog signal Y1, Y2 the BMC blocks calculate the distances between this input signal and all the possible code words. Since the code rate is one half in an example case, there are four different code words (C1,C2) and thus four BMC units 801. The trellis diagram distribution into the sub-trellises, the sub-trellis networks reuniting into a single trellis for the local state metric update and the trellis diagram redistribution into the sub-trellises for the next bit decoding are accomplished by the connection management block which consists the networks 802, 810 and 812. The network block 802 connects the calculated branch metrics to the corresponding states according to the trellis diagram. These values are added to the previous path metrics thus forming new state metrics 803. The states are distributed between the two processing units representing the polarity of the first input bit 804, 805. After the sub-trellis diagrams have reached their capacity, the decoded output is determined with the decision unit, which consists of the blocks 806, 807 and 809. In an example case, the 64-input minimum circuits 806, 807 are utilized to determine the most probable paths for the upper and lower processing units. From these selected paths a minimum value is determined 808 and this value is used for the bounding procedure of the state metrics at the next decoding cycle. By comparing the minimum values selected in 806 and 807, the decoded output of ‘0’ or ‘1’ is produced 809, depending on which processing unit contains the maximum likelihood path. In the differential Viterbi decoder separate data processing is applied for the local state metric update and for the output decoding. Referring to FIG. 1, the summation blocks 803 represent the left states 101 and 102 and the even states 101 are processed by the upper unit 804. Similarly, the odd states 102 are processed by the lower unit 805. The second network block 810 correspond the state relations in the trellis diagram shown in FIG. 1 104, 105, 106 and 107 thus performing the local trellis diagram reuniting procedure. The survivor path selection blocks, such as 807, are related to the right states in FIG. 1 109 and 110. In 811, the two-input minimum block determines the survivor path or maximum likelihood path for state 0 and the result is stored in a memory device, for example sample/hold (S/H) cell. At the next decoding cycle, these survivor metrics are read from the S/H cells and redistributed between the two sub-trellises with the aid of the third network block 812. Hence, the decoder in FIG. 8 obeys the trellis diagram reuniting-redistributing procedure and performs recursively differential decoding and local state metric update differentially.

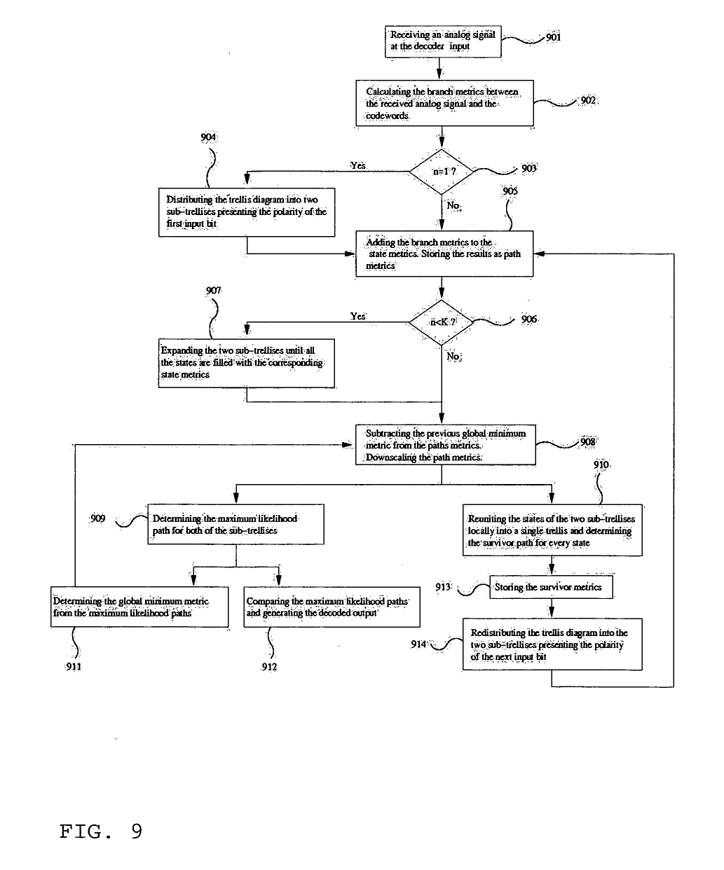

Flowchart of FIG. 9 illustrates a method for performing Viterbi decoding differentially with the local state metric update. The illustration is a special case with the code rate R of one half. The variable n is used to present the decoding cycle and the constraint length of the convolutional code is denoted by K. It is assumed that the state metrics are initialized to zero at the beginning of the decoding. In FIG. 9

on step 901, a signal (digital or analogue) corresponding the transmitted two-bit signal sequence, is received at the decoder input;

on step 902, the received signal is compared with all the possible codeword's and the results are denoted as branch metrics;

on step 903, it is checked, whether the current decoding cycle is the first one;

on step 904 the trellis diagram is distributed into the two sub-trellises according to the polarity of the first input bit similarly as presented in the fifth prior art;

on step 905 the branch metrics are summed with the previously calculated metrics, which are also called the state metrics, and the results are labelled as path metrics;

when the number of current decoding cycle n is smaller than the constraint length of the convolutional code K on step 906, the two sub-trellises are expanded on step 907 until all the states of the two sub-trellises are filled with the corresponding state metrics;

since the new branch metrics are summed with the previous state metrics on step 905, the path metrics tend to grow monotonically with time. In the fifth prior art by Demosthenous et. al this path metric overflow is avoided by resetting all the path metrics into zero between the consecutive decoding cycles. This method requires the decoding depth (i.e. the number of decoding cycles) of several times to the constraint length of the convolutional code to be used for decoding a single output bit. Therefore, the method presented in the fifth prior art is limited to convolutional codes with smaller constraint lengths and to moderate data rates. In order to enable codes with larger constraint lengths to be used with higher data rates a path metric renormalization procedure presented in the third prior art or other bounding procedure for the path metrics is required. In an example bounding procedure on step 908 of the method presented here, the global minimum (i.e. maximum likelihood) metric determined on the previous decoding cycle, is subtracted from the path metrics. The path metrics are further downscaled by a proper downscaling ratio. The subtraction and downscaling operations on step 908, keep the path metrics within a pre-specified range and enable the local state metric update accomplished on steps 910, 913 and 914;

on step 909 the maximum likelihood path is determined for both of the sub-trellises by selecting the paths with the largest log-likelihood functions;

on step 910 the two sub-trellises are locally reunited into a single trellis in such a way that there are two competing paths entering each state. The less probable paths are discarded and the remaining paths are labelled as survivor paths for each state;

on step 911, the global minimum metric is determined from the maximum likelihood paths selected on step 909. At the next decoding cycle, this metric is subtracted from the path metrics on step 908;

on step 912 the maximum likelihood paths for the two sub-trellises selected on step 909 are compared and the decoded output of ‘0’ or ‘1’ is produced depending on, whether the maximum likelihood path is in the upper or in the lower sub-trellis network;

on step 913 the survivor metrics determined on step 909 are temporarily memorized, until they are read out at the next decoding cycle;

on step 914 the trellis diagram is redistributed into the two sub-trellis networks so that the upper network consists of the even states and corresponds the next input bit of ‘0’, whereas the lower network consists of the odd states and corresponds the next input bit of ‘1’;

at the next decoding cycle the decoder performs all the steps presented in the flowchart, and on step 905 adds the new branch metrics to the previously calculated state metrics, which were locally updated on steps 909, 911 and 912 at the previous decoding cycle.

since separate data processing is applied for the steps 909, 911-912 and for the steps 910, 913-914, the decoding is differential and since the two sub-trellis networks are reunited on step 910 during the state metric update and redistributed again on step 914, the decoder is locally updating. The local state metric update is possible, since the path metric overflow is avoided by a bounding procedure, e.g. path metric downscaling and subtracting the global minimum metric determined on step 911 at the next decoding cycle on step 908.

1. A Viterbi decoder for real-time error correction, producing a decoded bit per cycle, the decoder comprising:
branch metric calculation blocks (801) for calculating the probabilities between code words and the received signal,
state metric calculation blocks (803),
decision blocks (806, 807, 809) for generating the decoded output sequence, and
survivor path selection blocks (811) for determining the maximum likelihood path for each state;
characterized in that decoding of a bit per cycle is enabled by connection management blocks (802, 810, 812) which are adapted to distribute a trellis diagram into two sub-trellises, to reunite the two sub-trellises locally into a single trellis between decoding cycles in order to update state metrics, the reuniting being performed in such a way that there are two competing paths entering each state, and to redistribute the trellis diagram into two sub-trellises for the next bit decoding, the sub-trellises representing the polarity of the next input bit.

2. A Viterbi decoder according to claim 1, characterized in that the monotonical growth of state metrics is avoided by a bounding procedure in a path metric update (808).

3. A Viterbi decoder according to claim 1, characterized in that the decision blocks (806, 807) comprise minimum circuits which are applied on the decision of the maximum likelihood path.

4. A Viterbi decoder according to claim 1, characterized in that the survivor path is determined by a comparator (809).

5. A Viterbi decoder according to claim 2, characterized in that the extracted minimum state metric from a previous decoding cycle is subtracted from all the state metrics in the bounding procedure and the state metrics are downscaled between decoding cycles.

6. A method for real-time Viterbi decoding, the method comprising the following steps:
calculating the branch metrics between the received analog signal and the codewords (902),
distributing the trellis diagram into two sub-trellises representing the polarity of the first input bit (904),
adding the branch metrics to the state metrics and storing the results as path metrics (905),
expanding the two sub-trellises until all the states are filled with the corresponding state metrics (907),
determining the maximum likelihood path for both of the sub-trellises (909), and
comparing the maximum likelihood paths and generating the decoded output (912); characterized in that decoding of a bit per cycle is enabled by:
reuniting the two sub-trellises locally into a single trellis in such a way that there are two competing paths entering each state, and determining the survivor path for every state (910),
storing the survivor metrics (913), and
redistributing the trellis diagram into two sub-trellises for the next bit decoding, the sub-trellises representing the polarity of the next input bit (914).

7. A method according to claim 6, characterized in that distributed trellis diagram is used for output decoding (912) and reunited trellis diagram is used for state-metric update (913).

8. A method according to claim 6, characterized in that the monotonical growth of state metrics is avoided by a bounding procedure in a path metric update (908).

9. A method according to claim 6, characterized in that the extracted minimum state metric from a previous decoding cycle (911) is subtracted from the path metrics and the path metrics are downscaled between decoding cycles (914).

10. A computer program, characterized in that it contains computer program code tools, which are organized to execute all phases of the method defined in claim 6 while executing the program in a computer.
